(19) United States
(12) Patent Application Publication
(10) Pub. No.: US 2014/0354335 A1
(43) Pub. Date: Dec. 4, 2014

(54) Digital Phase Locked Loop with Hybrid Delta-Sigma Phase/Frequency Detector

(71) Applicant: Broadcom Corporation, Irvine, CA (US)

(72) Inventors: Ioannis Loukas Syllaios, Costa Mesa, CA (US); Henrik Tholstrup Jensen, Long Beach, CA (US)

(73) Assignee: Broadcom Corporation, Irvine, CA (US)

(21) Appl. No.: 13/966,515

(22) Filed: Aug. 14, 2013

Related U.S. Application Data
(60) Provisional application No. 61/828,108, filed on May 28, 2013.
(60) Provisional application No. 61/856,278, filed on Jul. 19, 2013.

(51) Int. Cl. H03L 7/189

(52) U.S. Cl. CPC H03L 7/189
USPC 327/157

(57) ABSTRACT

A PLL includes independent frequency-locking and phase-locking operational modes. In addition, the PLL includes a hybrid (e.g., mixed-analog/digital signal) 2nd-order delta-sigma (DS) phase/frequency detector. The detector may be implemented based on a continuous-time 1st-order DS Analog to Digital (ADC) converter. The ADC may be enhanced to 2nd-order by using, e.g., closed loop frequency detection. The PLL includes a fine resolution encoder for encoding the DS ADC output. The fine resolution encoding facilitates true multi-bit phase/frequency error digitization with drastically reduced DS quantization noise.

### PRIORITY CLAIM

This application claims the benefit of priority to U.S. Provisional Application No. 61/828,108, filed 28 May 2013 and to U.S. Provisional Application No. 61/856,278, filed 19 Jul. 2013.

### TECHNICAL FIELD

This disclosure relates to phase locked loops (PLLs).

### BACKGROUND

Rapid advances in electronics and communication technologies, driven by immense customer demand, have resulted in the widespread adoption of an extensive variety of electronic devices. These devices often rely for proper operation on sophisticated frequency synthesizers, clock recovery circuits, jitter and noise reduction circuits and other types of circuits that are sometimes implemented with phase locked loops (PLLs). Improvements in PLLs will further enhance the performance of electronic devices.

### BRIEF DESCRIPTION OF THE DRAWINGS

FIG. 1 shows an example of a PLL.

FIG. 2 is an example of a hybrid 2nd-order delta sigma phase/frequency detector.

FIG. 3 is an example of a normalized discrete-time delta sigma detector model.

FIG. 4 shows an example of a fine resolution encoder.

FIG. 5 is an example of a digital loop filter and hybrid digital (HD) PLL dynamic control.

FIG. 6 shows selected WLAN 802.11ac channels between 4915 and 5825 MHz.

FIG. 7 shows example phase noise profiles.

FIG. 8 shows coarse resolution HDPLL phase noise performance.

FIG. 9 shows fine resolution HDPLL phase noise performance.

FIG. 10 shows HDPLL root-mean-square (RMS) phase error performance.

FIG. 11 shows an example of dynamic element matching used in connection with a Digital to Analog Converter (DAC) in a detector such as that of FIG. 2.

FIG. 12 shows another example PLL.

### DETAILED DESCRIPTION

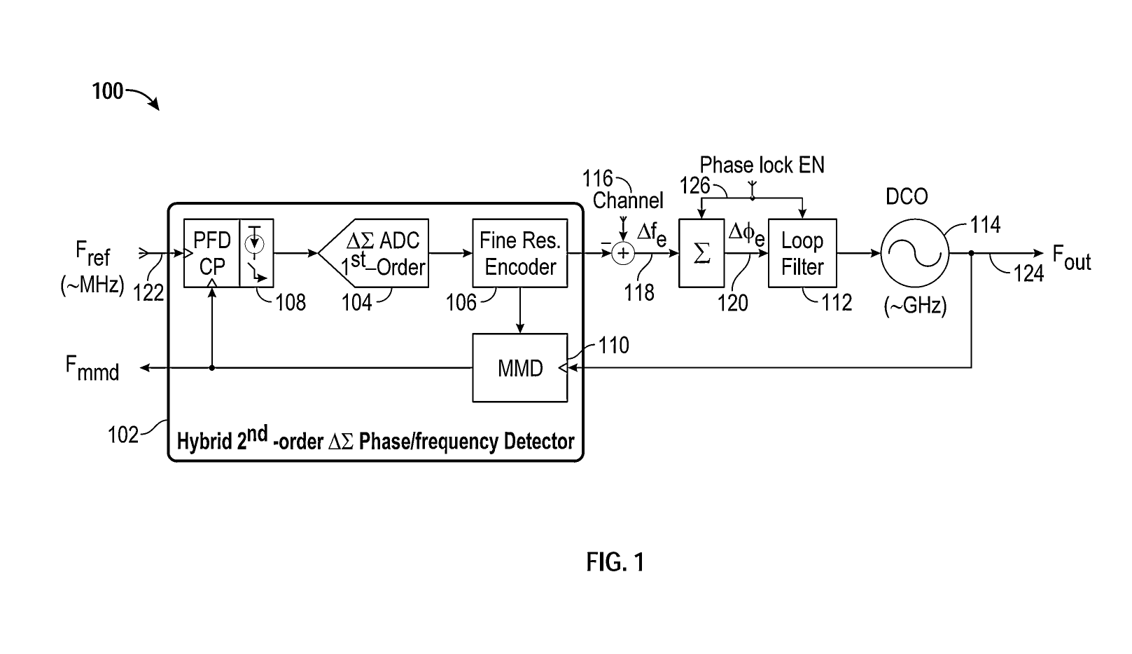

FIG. 1 shows an example of a PLL 100. The PLL 100 includes independent frequency-locking and phase-locking operational modes. In addition, the PLL 100 includes a hybrid (e.g., mixed-analog/digital signal) 2nd-order delta-sigma (DS) phase/frequency detector 102 (“detector 102”). The detector 102 may be implemented, for example, using a continuous-time 1st-order DS Analog to Digital Converter (ADC) 104, enhanced to 2nd-order via, e.g., closed loop frequency detection.

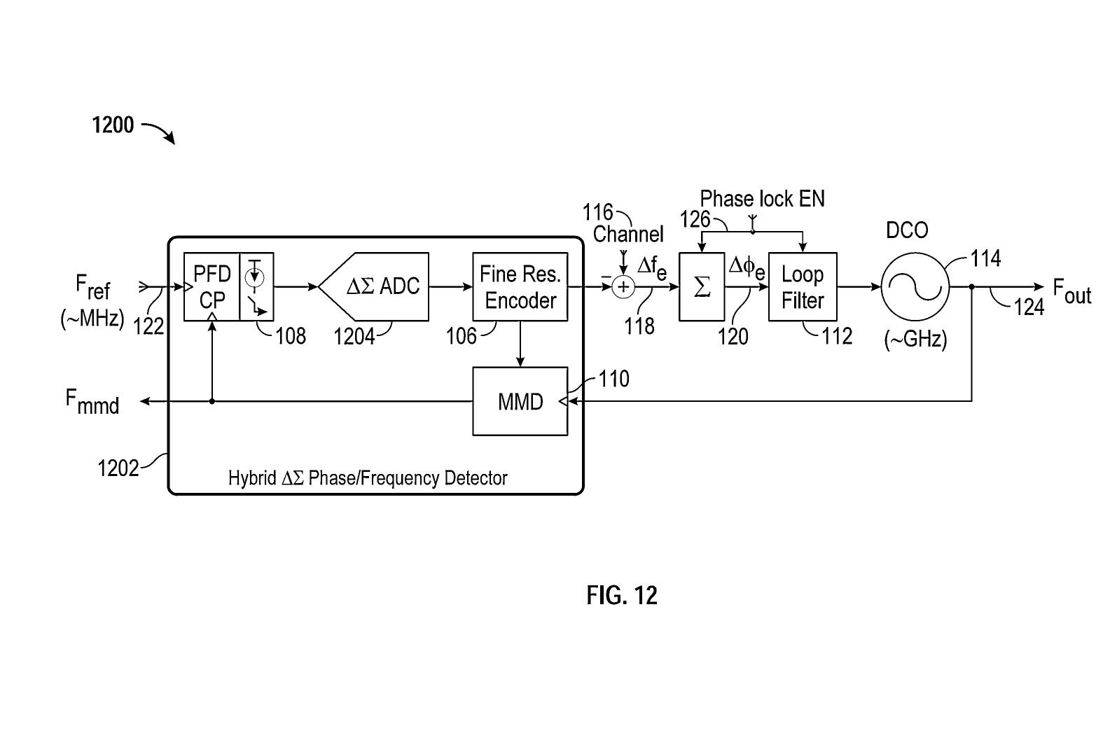

The PLL 100 and its component parts may be implemented in other ways and may vary in performance characteristics from implementation to implementation. For example, FIG. 12 shows another example PLL 1200. In the example of FIG. 12, a hybrid DS phase/frequency detector 1202 is present, and includes a DS ADC 1204 which is not necessarily 1st-order. As another example, in some implementations, an ADC with Dynamic Element Matching (DEM) may be used, while in other implementations, the DEM is omitted.

The PLL 100 includes a fine resolution (FineRes) encoder 106 for encoding the DS ADC output. The fine resolution encoding facilitates true multi-bit phase/frequency error digitization with drastically reduced DS quantization noise. A phase/frequency detector (PFD) charge pump (CP) 108 drives the ADC 104, and a multi-modulus divider (MMD) 110 is present in the feedback path from the digital loop filter.

The PLL 100 also includes coarse and fine resolution detection modes that facilitate fast acquisition and spur-free tracking operation. A fully digital loop filter 112 may be implemented in the PLL 100 and may control the digitally control oscillator (DCO) 114. Note that the PLL 100 has a bandwidth determined by the loop filter coefficients independent of the DS phase/frequency detector parameters (e.g., CP current I_{cp} and the 1st-order DS ADC integrating capacitor Cᵢₙₜ).

The PLL 100 operates on the differential phase/frequency error of its output clock signal Fₒᵤₜ with respect to the input reference clock signal 122, F_{ref}. The output frequency of the PLL output clock 124, Fₒᵤₜ, reflects the targeted channel frequency upon phase/frequency lock. The detector 102 provides a digital estimate of the PLL output frequency the PLL 100 may compare to a digital word (e.g., a channel indicator 116) that specifies the targeted channel frequency for the PLL 100 to produce. The digital frequency error information (Dfₑ) 118 is accumulated (e.g., integrated) to provide the digital phase error information (Dphiₑ) 120. The PLL 100 controls the phase/frequency of the DCO 114 responsive to the digital phase error information, e.g., to try to eliminate the error. A phase lock enable signal 126 may be provided to selectively enable or disable the operation of the accumulation and filter operations of the PLL 100.

Note that the loop filter configuration is independent of the fine resolution encoder 106. Without the fine resolution encoder 106, the loop filter may instead be characterized by a low bandwidth and high rejection (that may result in less stable output) so that distortion due to the coarse resolution quantization is adequately filtered. The fine resolution encoder 106 thus allows for more flexible PLL dynamic control.

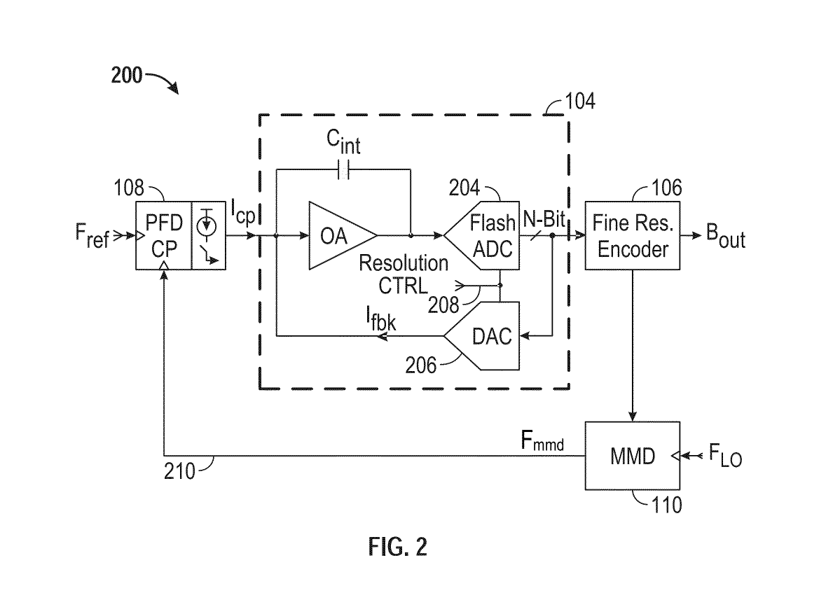

FIG. 2 is an example of a hybrid 2nd-order delta sigma phase/frequency detector (“detector”) 200 that may be used in the PLL 100, and also shows in more detail the ADC 104. The voltage developed across Cᵢₙₜ reflects the phase error between the reference clock (F_{ref}) and the divided local oscillator (LO) clock (F_{mmd}) on the divider output 210. The negative feedback loop around Cᵢₙₜ dynamically conditions charge accumulation and in the absence of overloading the detector self-calibrates Direct Current (DC) offsets. The closed loop noise shaping functionality of the detector 200 allows for low I_{cp} consumption and therefore relaxed CP phase noise performance. These advantages directly translate to small Cᵢₙₜ values, e.g., a few pico Farad (pF), with Cᵢₙₜ a function of I_{cp} and F_{ref}, e.g., Cᵢₙₜ˜f(I_{cp}/F_{ref}). In some analog CP-PLLs, the loop filter shunt capacitance is required to be large (on the order of hundreds of pF). This is because the loop bandwidth is a small fraction of F_{ref} for adequate suppression of high-frequency DS quantization noise. However, in the PLL 100, the purpose of Cᵢₙₜ is for detector gain normalization, and therefore is not subject to the same value requirements as in analog CP-PLLs.

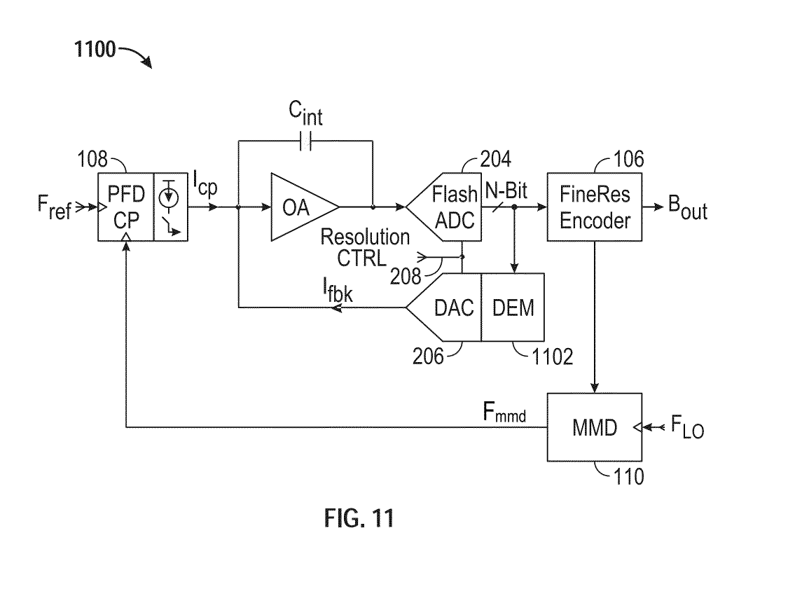

The flash ADC 204 and current-mode DAC 206 of the ADC 104 is digitally reconfigurable to support single-bit or multi-bit resolution via dynamic control of the number of active quantization levels, allowing for fast frequency acquisition and spur-free tracking operation. In that regard, the PLL 100 may include a resolution control input 208 that specifies, e.g., the number of quantization levels that the ADC 104 will generate. As a specific example, the resolution control input 208 may be provided to both the flash ADC 204 and the current-mode DAC 206 to configure them for the number of quantization levels desired. A controller may use the resolution control input 208 to place the PLL 100 into single-bit or three level quantization mode for coarse resolution operation of the PLL 100, while the controller may cause multi-bit quantization for fine resolution operation of the PLL 100. The controller may switch to fine resolution operation on an application specific basis, and as one example the switch to fine resolution may depend upon the time for the frequency error to settle to within a predefined margin. To the extent that there are mismatches in the flash ADC 204 and current-mode DAC 206 characteristics, those mismatches may be randomized via the closed-loop noise shaping functionality of the detector 200, thereby alleviating any need for dynamic element matching (DEM). However, as noted below with respect to FIG. 11, DEM may also be included.

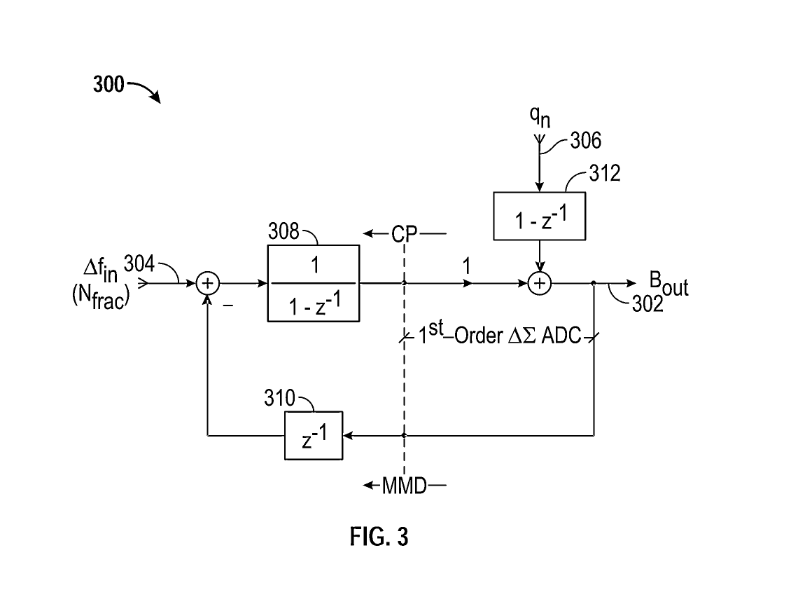

FIG. 3 is an example of a normalized discrete-time delta sigma detector model 300. The MMD 110 divides F_{LO} by a sequence of integer factors of the form:

Nᵢₙₜ+{ . . . ,−1,0,1, . . . }

and thereby achieves a long-term average fractional N value, where:

N=Nᵢₙₜ+N_{frac}=F_{LO}/F_{ref} and N_{frac}ε[0,1) or [−½,½).

The mean value of the detector output Bₒᵤₜ 302 is preferably N_{frac} in order to minimize the frequency error between F_{ref} and F_{mmd}=F_{LO}/(Nᵢₙₜ+N_{frac}). The fractional division control results in N_{frac} cycle-to-cycle period variations of F_{mmd}, which entail a N_{frac} LO cycles normalized differential frequency Delta fᵢₙ input 304 to the DS detector.

Delta fᵢₙ (N_{frac}) 304 and the induced 1st-order DS ADC quantization noise Qₙ 306 are transferred to the detector output 302 as:

Bₒᵤₜ=N_{frac}+(1−z¹)²Qₙ

Note that the induced quantization noise undergoes 2nd-order noise shaping.

In FIG. 3, the z-domain transfer function 308 represents the sampled physical integration of frequency error reflected on the pulse-width modulated CP output current (hence ←CP), in response to the previous (equation 310) output sample of the DS ADC output fed to the MMD control (hence ←MMD), and the equation 312 represents first-order noise shaping functionality of the DS ADC.

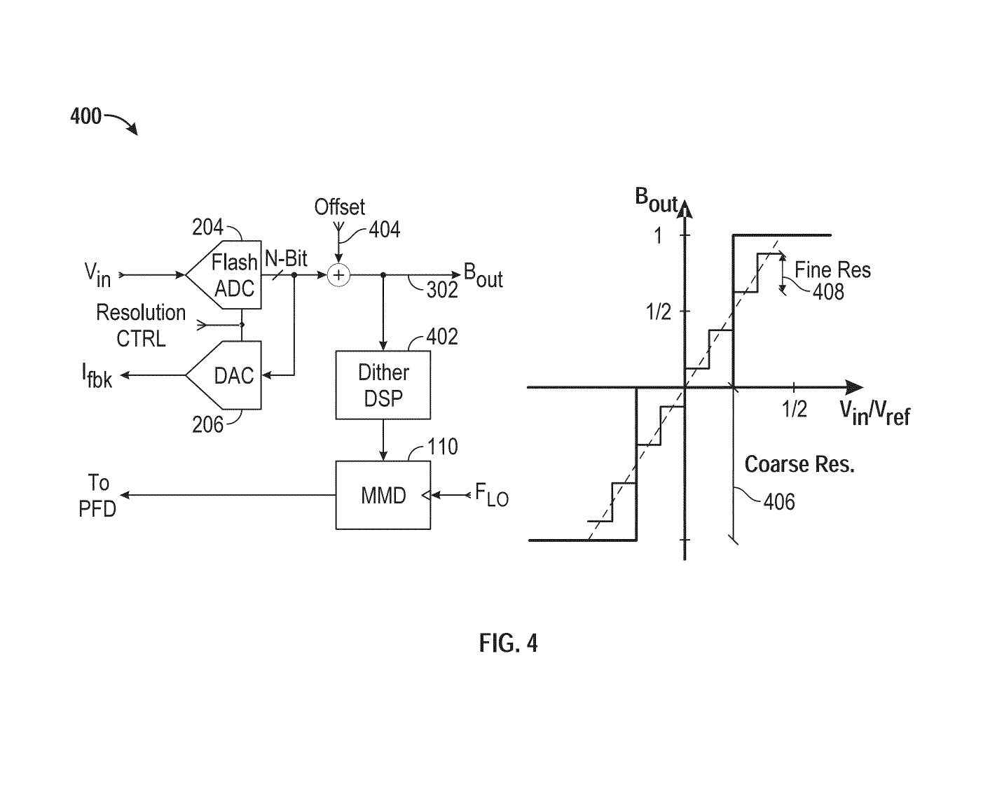

FIG. 4 shows an example of a fine resolution encoder circuit 400 that may be used in the PLL 100. For integer only MMD control a suitable coarse quantization step for the 1st-order DS ADC is D=1 and a mid-tread three-level quantizer {−1,0,1} may suffice to produce the N_{frac} values. Additional levels may not improve performance because it may be difficult or impossible to further reduce the induced quantization noise power (which is on the order of Delta²/12 in this implementation example).

FIG. 4 also illustrates the difference between coarse resolution encoding 406 and fine resolution encoding 408. The ADC resolution can be increased to support multi-bit (fine) resolution (i.e., Delta (D)<1) when integer only MMD control is maintained. The PLL 100 may achieve increased ADC resolution with concurrent re-encoding of the ADC output. The re-encoding may be, for example, to integer only valued control through dither Digital Signal Processing (DSP) operations, such as a digital Multi-Stage Noise Shaping (MASH) (e.g., a MASH-III) DS modulator implemented with the dither DSP 402. Preferably, the modulator does not degrade the 2nd-order DS noise shaping characteristics of the detector 102. The detector capability to dynamically self-calibrate DC offsets allows the 1st-order DS ADC quantizer input voltage to be maintained at a predetermined DC level after proper digital output offsetting. The digital offset input 404 provides better control for preventing quantizer overloading and maintaining uniform ADC operation across all channels (i.e., all N_{frac} values).

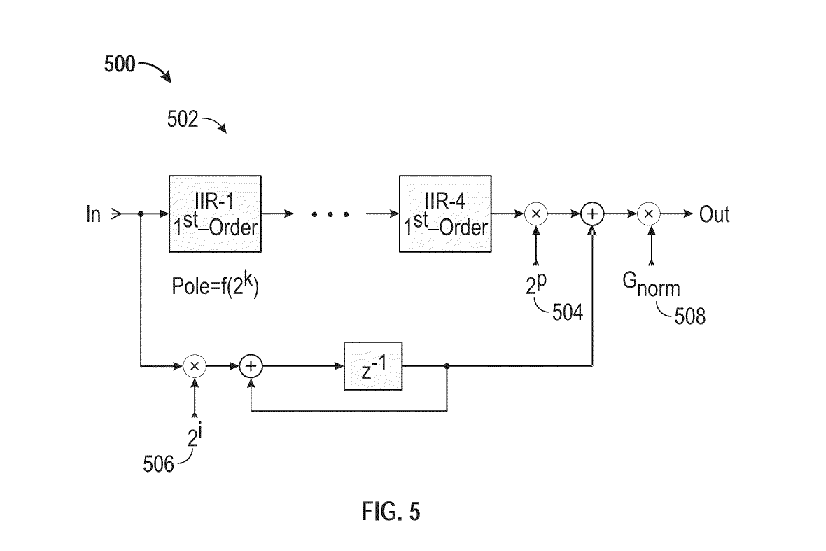

FIG. 5 is an example of a digital loop filter 500 for the dynamic control of the hybrid digital (HD) PLL. The digital loop filter 500 is one possible implementation of the loop filter 112, with reference again to FIG. 1. The digital loop filter 500 may include proportional-plus-Integral (P+I) control for type-II operation, e.g., so that the phase error between the output clock signal and the reference clock signal is approximately zero, combined with cascaded single-pole IIR filters 502 that facilitate achieving high rejection of the DS detector quantization noise. The HDPLL loop gain may be normalized via the gain normalization (Gₙₒᵣₘ) factor 508. The gain normalization factor 508 may decouple the HDPLL dynamic operation from process, voltage, temperature (PVT) dependent parameters such as the DCO gain. The PLL 100 may implement filter coefficients (e.g., 504, 506) that are powers of two, and therefore facilitate digital hardware implementation, e.g., as digital bit-shifting operations. None of the factors, including the gain normalization factor Gₙₒᵣₘ 508, need to be a power of two, however. The digitally intensive HDPLL dynamic control facilitates on-demand bandwidth control, sometimes referred to as gear shifting. The dynamic control also effectively addresses parasitic spurious noise, e.g., injected via the power supplies or coupling between the DCO and the crystal (Xtal) reference.

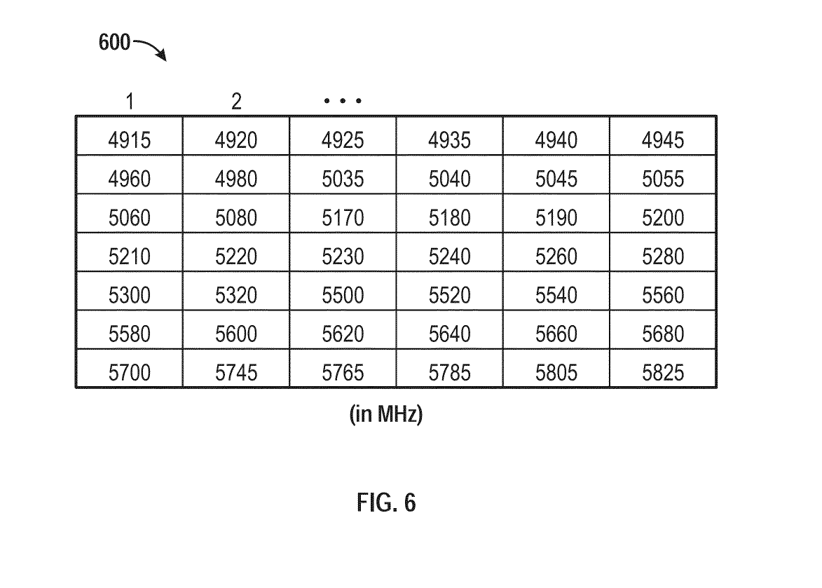

FIG. 6 shows examples of channel frequencies 600 in MHz that the PLL 100 may generate. One specific example is 4915 MHz (4.915 GHz). Note that the PLL 100 may generate any desired output frequencies, including those shown in FIG. 6. The output frequencies may vary widely according the particular system (e.g., a 3G or 4G cellular phone, or a Bluetooth transceiver) in which the PLL 100 is present.

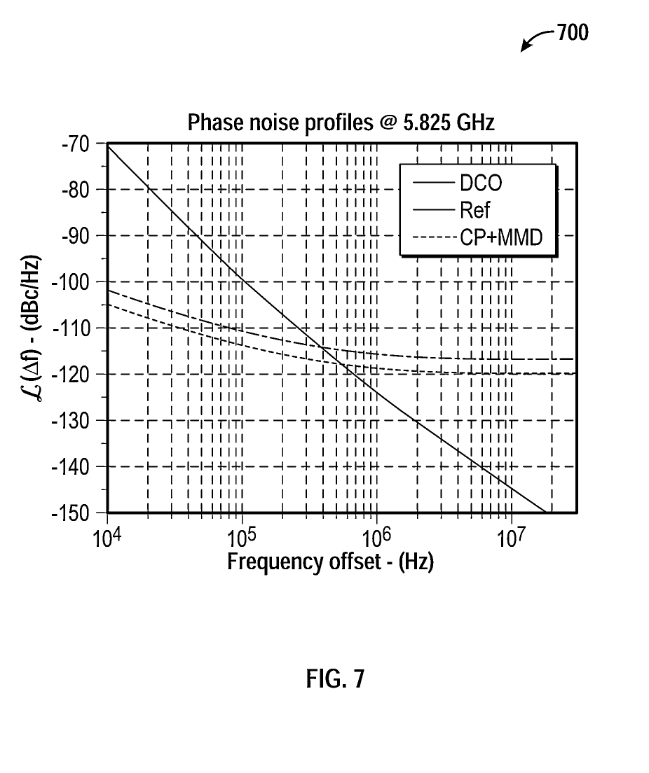

FIG. 7 shows the phase noise profiles 700 for the PLL 100. The dataset is for 5.825 GHz. The dataset shows the phase noise profile for the DCO 114, the charge pump 108 and MMD 110, compared to a reference.

Fine resolution encoding may generally refer to a quantization step D less than 1. The PLL 100 uses quantization steps less than one (D<1) together with the fine resolution encoder 106 to interface the fractional valued DS ADC output with the MMD 110. The quantization step may be set according to a targeted PLL performance. Accordingly, even low-level fractional quantization may be sufficient for a target performance level, and finer grained fractional quantization may be implemented to reach higher target performance levels.

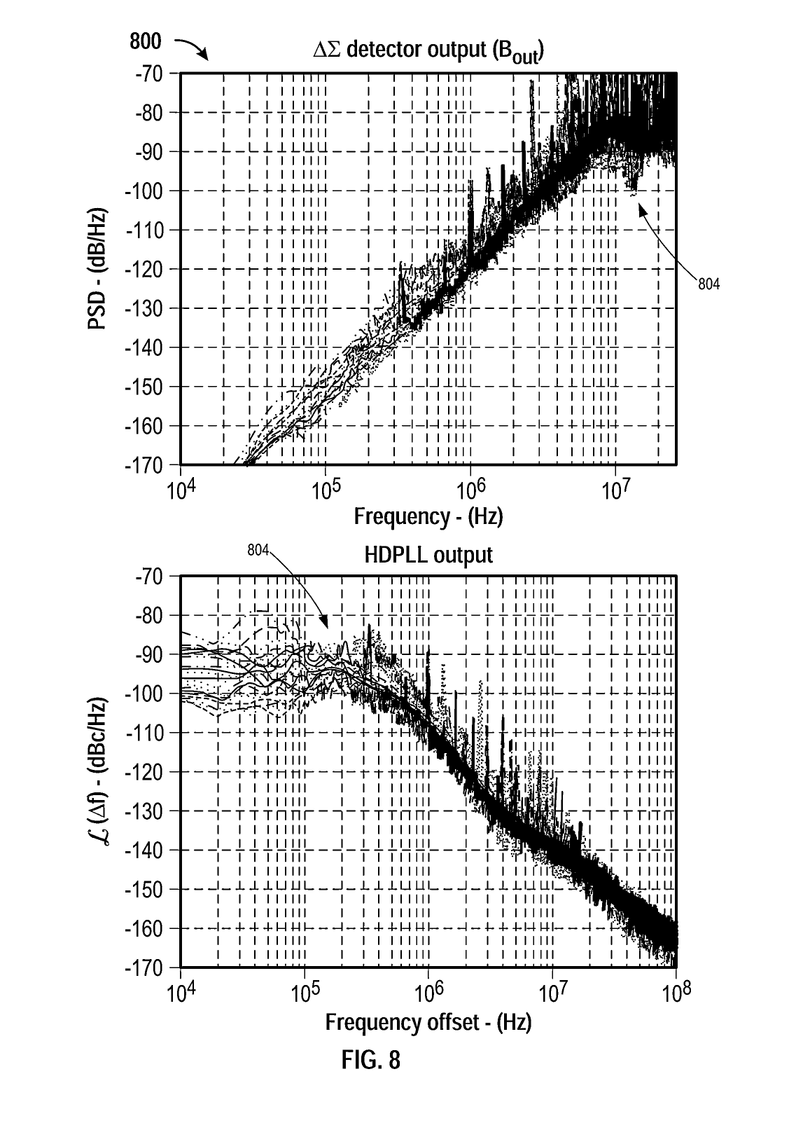

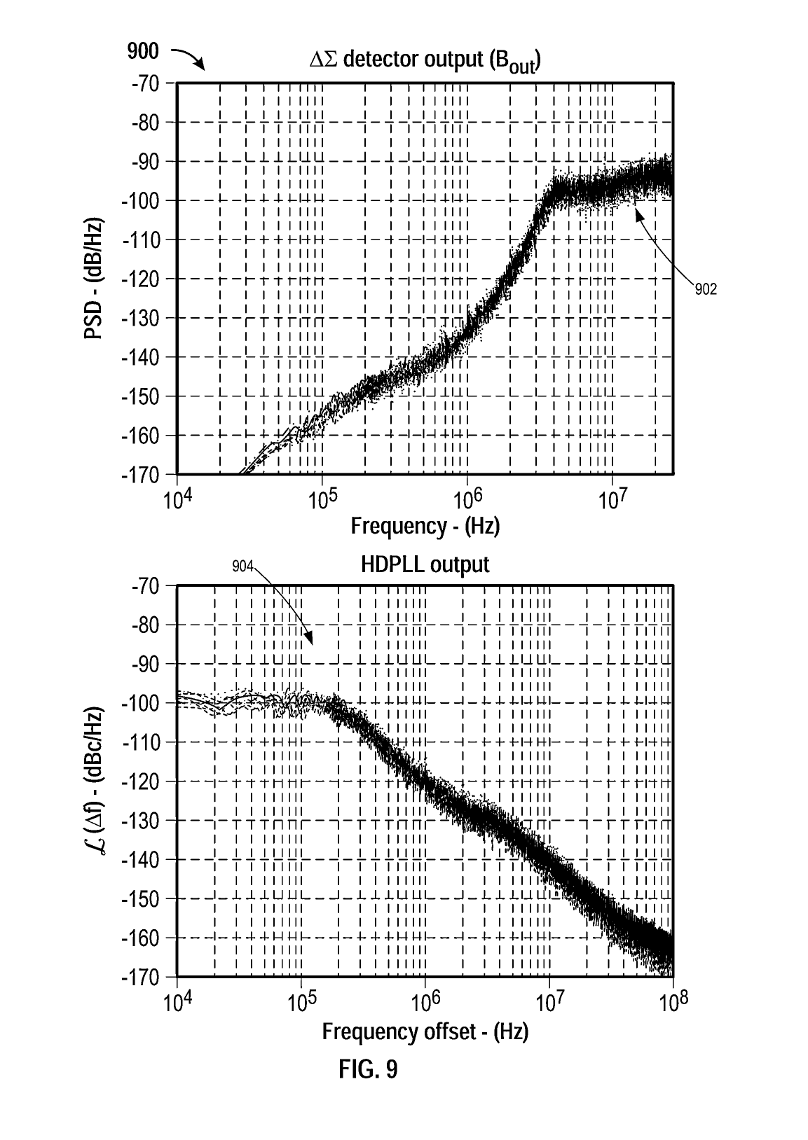

FIG. 8 shows 3-level {−1, 0, 1} coarse resolution HDPLL phase noise performance 800 for a 5 GHz spectrum. Note the DS detector output variance 802, and the HDPLL output variance 804. FIG. 9 shows 16-level fine resolution HDPLL phase noise performance 900, also for the 5 GHz spectrum. Note the significantly reduced and spurious tones-free DS detector output variance 902, and the HDPLL output variance 904.

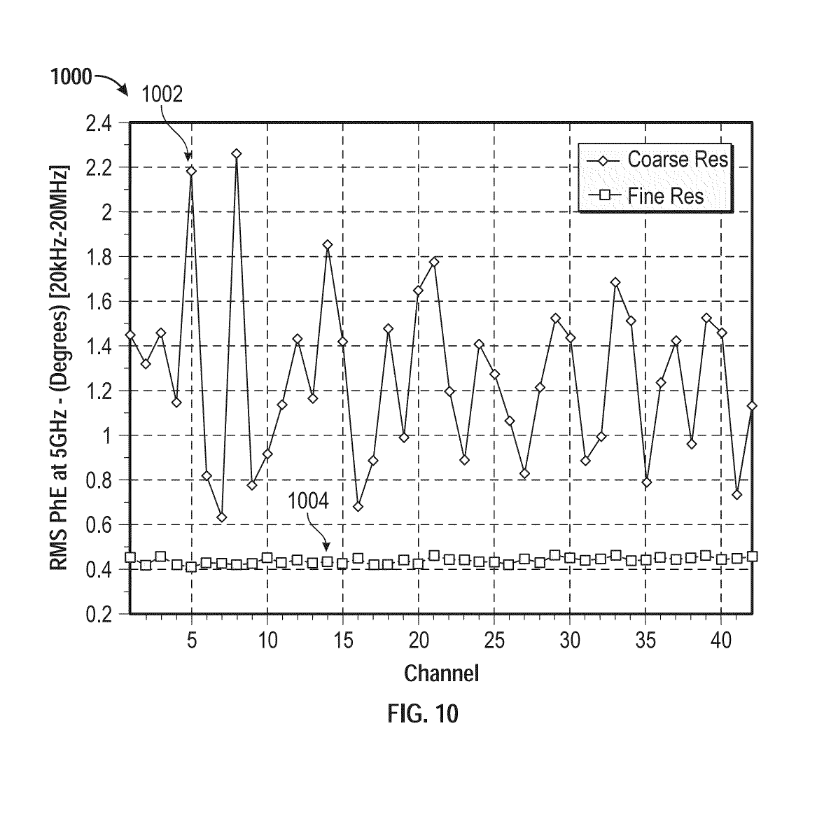

FIG. 10 shows HDPLL root-mean-square (RMS) phase error performance 1000. The phase error performance 1002 for coarse resolution operation mode is shown. Also shown is the phase error performance 1004 for fine resolution operation mode. Fine resolution mode exhibits significantly reduced RMS phase error across all of the channels of interest.

FIG. 11 shows an example of a detector 1100 that uses optional dynamic element matching in connection with a Digital to Analog Converter (DAC). In particular, the dynamic element matching circuitry 1102 is associated with (e.g., incorporated into) the current-mode DAC 206. In the DAC 206 a series of unit current sources may generate the analog output. However, due to the normal variations in the fabrication processes, each unit current source is not exactly the same, and each may vary slightly from each other current source. The dynamic element matching circuitry 1102 may be present to help eliminate the mismatches as a source of error. The dynamic element matching circuitry 1102 may implement, for example, the randomized use of the unit current sources in order to make the error resulting from their mismatches appear to be pseudorandom noise (e.g., white noise) that is uncorrelated with the input.

Various implementations of the PLL 100 have been specifically described. However, many other implementations are also possible.

What is claimed is:

1. A phase locked loop (PLL) comprising:
a reference frequency input;
a detector in communication with the reference frequency input, the detector comprising a fine resolution encoder configured to output a multiple bit resolution phase/frequency error encoding;
a loop filter following the detector and configured to accept the multiple bit resolution error encoding; and
a reference frequency output following the loop filter.

2. The PLL of claim 1, where the detector comprises a phase and frequency detector including an analog to digital converter (ADC).

3. The PLL of claim 2, where the ADC is configured to selectively operate in:
a fine resolution mode providing a fine mode number of quantization levels; and
a coarse resolution mode providing fewer quantization levels than the fine mode number of quantization levels.

4. The PLL of claim 3, where the coarse resolution mode provides at least two quantization levels.

5. The PLL of claim 3, where the fine resolution mode provides at least eight quantization levels.

6. The PLL of claim 2, where the ADC comprises a delta-sigma ADC.

7. The PLL of claim 6, where the detector further comprises a charge pump configured to drive the delta-sigma ADC.

8. The PLL of claim 1, further comprising a digitally controller oscillator (DCO) driven by the loop filter, the DCO configured to generate a target output frequency signal on the target frequency output.

9. The PLL of claim 8, further comprising:
a feedback path from the DCO to the detector, the feedback path configured to provide the target frequency output to the detector.

10. The PLL of claim 9, where the feedback path comprises a multi-modulus divider (MMD) configured to receive the target frequency output.

11. The PLL of claim 10, further comprising a dither circuit configured to interface the fine resolution encoder to the MMD.

12. The PLL of claim 11, where the multi-modulus divider comprises a divider output that provides feedback to a phase and frequency detector (PFD) charge pump.

13. The PLL of claim 12, where the PFD charge pump drives a delta-sigma ADC in communication with the fine resolution encoder.

14. A method comprising:
performing phase/frequency detection with respect to a reference frequency and a feedback signal;
generating, with a fine resolution encoder, a multiple bit error encoding of phase/frequency error responsive to the detection;
receiving the multiple bit error encoding at a loop filter; and
controlling a digitally controller oscillator (DCO) with the loop filter to generate a reference frequency output.

15. The method of claim 14, further comprising:
generating the feedback signal by applying a multimodulus divider (MMD) to the reference frequency output.

16. The method of claim 15, further comprising:
dithering the multiple bit error encoding to interface the fine resolution encoder to the MMD.

17. The method of claim 14, further comprising configuring an analog to digital converter (ADC) to act in a fine resolution mode to provide the fine resolution encoder that generates the multiple bit error encoding.

18. The method of claim 17, further comprising configuring the ADC to act in a coarse resolution mode for acquisition of frequency lock.

19. A phase locked loop (PLL) comprising:
a reference frequency input;
a phase and frequency detector charge pump in communication with the reference frequency input;
a delta signal analog to digital converter (ADC) driven by the charge pump, the ADC comprising a resolution mode input configured to selectively change the ADC between:
a fine resolution mode providing a fine mode number of quantization levels for phase and frequency error; and
a coarse resolution mode providing fewer quantization levels for the phase and frequency error than the fine mode number of quantization levels;
a loop filter following the ADC and configured to accept the phase and frequency error and responsively drive a digitally controlled oscillator (DCO) that generates a reference frequency output; and
a feedback path from the DCO to the charge pump, the feedback path comprising a multimodulus divider (MMD).

20. The PLL of claim 19, further comprising a dither circuit configured to interface the fine mode number of quantization levels to a lower-resolution MMD control grid of the MMD.
